(19) United States
(12) Patent Application Publication
(10) Pub. No.: US 2016/0240748 A1
(43) Pub. Date: Aug. 18, 2016

(54) SINGLE-CRYSTAL PHOSPHOR AND LIGHT-EMITTING DEVICE

(71) Applicants: KOHA CO., LTD., Tokyo (JP); NATIONAL INSTITUTE FOR MATERIALS SCIENCE, Ibaraki (JP)

(72) Inventors: Daisuke Inomata, Tokyo (JP); Kazuo Aoki, Tokyo (JP); Kiyoshi Shimamura, Ibaraki (JP); Encarnacion Antonia Garcia Villora, Ibaraki (JP)

(73) Assignees: KOHA CO., LTD., Tokyo (JP); NATIONAL INSTITUTE FOR MATERIALS SCIENCE, Ibaraki (JP)

(21) Appl. No.: 15/030,689

(22) PCT Filed: Oct. 20, 2014
(86) PCT No.: PCT/JP2014/077843

§ 371 Date: Apr. 20, 2016

(30) Foreign Application Priority Data
Oct. 23, 2013 (JP) 2013-220682

(51) Int. Cl. H01L 33/50; C09K 11/77

(52) U.S. Cl. CPC H01L 33/502; C09K 11/7774

(57) ABSTRACT

As one of purposes, the present invention provides: a single-crystal phosphor which can exhibit excellent properties under high-temperature conditions; and a light-emitting device in which the phosphor is used. As one embodiment, a single-crystal phosphor is provided, which has a chemical composition represented by the compositional formula: (Y_{1-x-y-z}LuₓGd_{y}Ce_{z})₃₊ₐAl₅₋ₐO₁₂(0≦x≦0.9994, 0≦y≦0.0669, 0.0002≦z≦0.0067, −0.016≦a≦0.315).

### TECHNICAL FIELD

This invention relates to a single crystal phosphor and a light emitting device.

### BACKGROUND ART

A light emitting device is known which has a light emitting element comprised of an LED (light emitting diode) that emits blue light, and a phosphor that is excited by the light from that light emitting element and emits yellow light, to mix these emission colors to thereby radiate white light (see PTL 1 below, for example).

The light emitting device disclosed in PTL 1 is configured such that a particulate phosphor is contained in an epoxy resin and is disposed around the light emitting element for emitting blue light, to mix the light emitted by the light emitting element itself, and the yellow light emitted by the phosphor to thereby radiate white light.

### CITATION LIST

### Patent Literature

### [PTL 1]

### JP-A-2010-155891

### SUMMARY OF INVENTION

### Technical Problem

Due to increases in power of the light emitting device, heat generation by the light emitting element may be a significant problem. Specifically, variations in light emission properties due to power fed to the element, and variations in properties caused by temperature rising of the phosphor affect each other, thereby leading to variations in properties of the light emitting device.

The phosphor generally has its inherent quantum efficiency (efficiency of converting exciting light to fluorescence) and its temperature quenching property (property that the quantum efficiency decreases with increasing temperature). The higher quantum efficiency allows for achieving the higher-intensity light emitting device using the phosphor, while the superior temperature quenching property allows use of the phosphor in the higher power light emitting device.

Thus, it is an object of the present invention to provide a single crystal phosphor that exhibits superior properties even under high temperature conditions, as well as a light emitting device using the phosphor.

### Solution to Problem

According to an embodiment of the invention, to achieve the above object, a single crystal phosphor defined by [1] to [7] below will be provided.

[1]A single crystal phosphor, comprising a composition represented by a composition formula (Y_{1-x-y-z}LuₓGd_{y}Ce_{z})₃₊ₐAl₅₋ₐO₁₂(0≦x≦0.9994, 0≦y≦0.0669, 0.0002≦z≦0.0067, −0.016≦a≦0.315).

[2] The single crystal phosphor according to [1], wherein a fluorescence peak wavelength at a temperature of 25 degrees C. and an exciting light peak wavelength of 450 nm is not shorter than 514 nm and not longer than 544 nm, and wherein an internal quantum efficiency at a temperature of 300 degrees C. and an exciting light peak wavelength of 450 nm is not lower than 0.90.

[3] The single crystal phosphor according to [1], wherein a fluorescence peak wavelength at a temperature of 25 degrees C. and an exciting light peak wavelength of 450 nm is longer than 544 nm and not longer than 546 nm, and wherein an internal quantum efficiency at a temperature of 300 degrees C. and an exciting light peak wavelength of 450 nm is not lower than 0.80.

[4] The single crystal phosphor according to [1] or [2], wherein a fluorescence peak wavelength at a temperature of 25 degrees C. and an exciting light peak wavelength of 450 nm is not shorter than 514 nm and not longer than 544 nm, and wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.90.

[5] The single crystal phosphor according to [1] or [3], wherein a fluorescence peak wavelength at a temperature of 25 degrees C. and an exciting light peak wavelength of 450 nm is longer than 544 nm and not longer than 546 nm, and wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.80.

[6] The single crystal phosphor according to [1] or [2], wherein a fluorescence peak wavelength at a temperature of 25 degrees C. and an exciting light peak wavelength of 450 nm is not shorter than 514 nm and not longer than 544 nm, and wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.85.

[7] The single crystal phosphor according to [1] or [3], wherein a fluorescence peak wavelength at a temperature of 25 degrees C. and an exciting light peak wavelength of 450 nm is longer than 544 nm and not longer than 546 nm, and wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.80.

Also, according to another embodiment of the invention, to achieve the above object, a light emitting device defined by [8] will be provided.

[8]A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to any one of [1] to [3].

[9]A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to [4].

[10]A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to [5].

[11]A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to [6].

[12]A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to [7].

### Advantageous Effects of the Invention

According to an embodiment of the invention, a single crystal phosphor can be provided that exhibits superior properties even under high temperature conditions, as well as a light emitting device using the phosphor.

### BRIEF DESCRIPTION OF DRAWINGS

FIG. 1 is a cross sectional view schematically showing a pulling of a single crystal phosphor ingot by the CZ method in a first embodiment.

FIG. 2A is a graph showing relationships between the fluorescence peak wavelength (nm) and the internal quantum efficiency ηᵢₙₜ (300 degrees C.), of single crystal phosphors in the first embodiment.

FIG. 2B is a graph showing relationships between the fluorescence peak wavelength (nm), and the value of the internal quantum efficiency ratio, ηᵢₙₜ (300 degrees C.)/ηᵢₙₜ (25 degrees C.), of the single crystal phosphors in the present embodiment.

FIG. 3 is a graph showing relationships between the fluorescence peak wavelength (nm), and the value of the external quantum efficiency ratio ηₑₓₜ (300 degrees C.)/ηₑₓₜ (25 degrees C.), of the single crystal phosphors in the first embodiment.

FIG. 4A is a vertical cross sectional view showing a light emitting device in a second embodiment.

FIG. 4B is a vertical cross sectional view showing a light emitting element constituting that light emitting device and its peripheral portion.

FIG. 5A is a vertical cross sectional view showing a light emitting device in a third embodiment.

FIG. 5B is a vertical cross sectional view showing a light emitting element constituting that light emitting device.

FIG. 5C is a plan view showing the light emitting element.

FIG. 6 is a vertical cross sectional view showing a light emitting device in a fourth embodiment.

FIG. 7 is a vertical cross sectional view showing a light emitting device in a fifth embodiment.

FIG. 8A is a vertical cross sectional view showing a light emitting device in a sixth embodiment.

FIG. 8B is a vertical cross sectional view showing a light emitting element constituting that light emitting device.

FIG. 9 is a vertical cross sectional view showing a light emitting device in a seventh embodiment.

FIG. 10A is a vertical cross sectional view showing a light emitting device in an eighth embodiment.

FIG. 10B is a vertical cross sectional view showing a light emitting device constituting that light emitting device and its peripheral portion.

FIG. 11 is a vertical cross sectional view showing a light emitting device in a ninth embodiment.

### DESCRIPTION OF EMBODIMENTS

### First Embodiment

### Single Crystal Phosphor

A single crystal phosphor in a first embodiment is an yttrium aluminum garnet (YAG) based phosphor having an Y₃Al₅O₁₂ (YAG) crystal as a parent crystal, and has a composition represented by the composition formula (Y_{1-x-y-z}LuₓGd_{y}Ce_{z})₃₊ₐAl₅₋ₐO₁₂(0≦x≦0.9994, 0≦y≦0.0669, 0.0002≦z≦0.0067, −0.016≦a≦0.315). Here, the Lu and Gd are components which do not act as an emission center to be substituted in place of the Y The Ce is a component (activator) that can act as an emission center to be substituted in place of the Y.

It should be noted that, of the composition of the above mentioned single crystal phosphor, some atoms may occupy different crystal structural positions. Also, the value of O in the composition ratio in the above composition formula is written as 12, but the above-described composition includes a composition whose O value in the composition ratio slightly deviates from 12 due to inevitable ingress or loss of oxygen. Also, the value of a in the composition formula is an inevitably varying value in the production of the single crystal phosphor, but changes within the numerical range of the order of −0.016≦a≦0.315 have little effect on the physical properties of the single crystal phosphor.

Also, the phosphor of the present embodiment is free of group 2 elements such as Ba, Sr, etc., and group 17 elements such as F, Br, etc., and has a high purity. These features allow for ensuring the high intensity and long life phosphor.

The range of the value of z in the composition formula representing the Ce concentration is 0.0002≦z≦0.0067, because when the value of y is smaller than 0.0002, the Ce concentration is too low, therefore the absorption of exciting light decreases, and the external quantum efficiency is too low, while when the value of y is greater than 0.0067, cracks, voids or the like form when an ingot of the single crystal phosphor is grown, and the crystal quality is highly likely to degrade.

This single crystal phosphor can be produced, for example by a liquid phase growth method such as the CZ method (Czochralski Method), the EFG method (Edge Defined Film Fed Growth Method), the Bridgman method, the FZ method (Floating Zone Method), the Bernoulli method, or the like. By cutting the ingot of the single crystal phosphor obtained by these liquid-phase growth methods into a flat plate shape, or by pulverizing that ingot into powder, it can be used in a light emitting device to be described later.

The single crystal phosphor of the present embodiment has superior internal quantum efficiency. For example, the internal quantum efficiency is not lower than 0.91 at a temperature of 25 degrees C. and an exciting light peak wavelength of 450 nm.

According to the literature Solid-State Lighting Research and Development: Multi Year Program Plan March 2011 (Updated May 2011) P.69, Table A1.3, it is described that the numerical value in the year 2010 of the internal quantum efficiency (Quantum Yield (25 degrees C.) across the visible spectrum) is 0.90, and the year 2020 target value is to be 0.95. From this, it is seen that in the industry, a quantum efficiency enhancement on the order of 0.01 in 2 years is expected, and it can be said that the phosphor of the present embodiment is the superior phosphor having a quantum efficiency close to, or exceeding that targeted value at the time of filing.

Further, at least some of the single crystal phosphors of the present embodiment (though its details will be described later) have an internal quantum efficiency of not lower than 0.90 at a temperature of 300 degrees C. and an exciting light peak wavelength of 450 nm, in a sample whose fluorescence peak wavelength is not shorter than 514 nm and not longer than 544 nm at a temperature of 25 degrees C. and an exciting light peak wavelength of 450 nm.

Further, in a sample whose fluorescence peak wavelength is longer than 544 nm and not longer than 546 nm at a temperature of 25 degrees C. and an exciting light peak wavelength of 450 nm, the internal quantum efficiency is not lower than 0.80 at a temperature of 300 degrees C. and an exciting light peak wavelength of 450 nm.

These single crystal phosphors can maintain a high internal quantum efficiency even under a high temperature condition of 300 degrees C., therefore can exhibit their superior function as phosphors to be used in light emitting devices having a very high intensity per unit area, such as laser projectors or laser headlights whose exciting light is laser light.

Further, the single crystal phosphors exhibiting the high internal quantum efficiency at the above described temperature of 300 degrees C. have a superior temperature quenching property. For example, in a sample whose fluorescence peak wavelength is not shorter than 514 nm and not longer than 544 nm at a temperature of 25 degrees C. and an exciting light peak wavelength of 450 nm, the value of the ratio of the internal quantum efficiency at a temperature of 300 degrees C. and an exciting light peak wavelength of 450 nm, to the internal quantum efficiency at a temperature of 25 degrees C. and an exciting light peak wavelength of 450 nm is not lower than 0.90.

Further, in a sample whose fluorescence peak wavelength is longer than 544 nm and not longer than 546 nm at a temperature of 25 degrees C. and an exciting light peak wavelength of 450 nm, the value of the ratio of the internal quantum efficiency at a temperature of 300 degrees C. and an exciting light peak wavelength of 450 nm, to the internal quantum efficiency at a temperature of 25 degrees C. and an exciting light peak wavelength of 450 nm is not lower than 0.80.

Further, for example, in a sample whose fluorescence peak wavelength is not shorter than 514 nm and not longer than 544 nm at a temperature of 25 degrees C. and an exciting light peak wavelength of 450 nm, the value of the ratio of the external quantum efficiency at a temperature of 300 degrees C. and an exciting light peak wavelength of 450 nm, to the external quantum efficiency at a temperature of 25 degrees C. and an exciting light peak wavelength of 450 nm is not lower than 0.85.

Further, in a sample whose fluorescence peak wavelength is longer than 544 nm and not longer than 546 nm at a temperature of 25 degrees C. and an exciting light peak wavelength of 450 nm, the value of the ratio of the external quantum efficiency at a temperature of 300 degrees C. and an exciting light peak wavelength of 450 nm, to the external quantum efficiency at a temperature of 25 degrees C. and an exciting light peak wavelength of 450 nm is not lower than 0.80.

[Comparison with a Poly Crystal Phosphor]

A YAG based single crystal phosphor and a YAG based poly crystal phosphor powder, which are activated by Ce, significantly differ in the relationship between the Ce concentration and the emission color. For example, a patent document (JP-A-2010-24278) describes that a poly crystal phosphor powder having a composition represented by the composition formula (Y_{1-z}Ce_{z})₃Al₅O₁₂ emits light of a constant chromaticity (0.41, 0.56) in a Ce concentration range of 0.003≦z≦0.2. On the other hand, in the single crystal phosphor of the present embodiment, the chromaticity varies depending on the Ce concentration, and for example, the composition to emit light of the same chromaticity (0.41, 0.56) as that of the poly crystal phosphor powder of the above patent document is (Y_{1-z}Ce_{z})₃Al₅O₁₂ (z=0.0005).

Also, another patent document (JP-B-3503139) describes that a poly crystal phosphor powder having a composition represented by the composition formula (Y_{1-a-b}LuₐCe_{b})₃Al₅O₁₂ has an emission chromaticity of (0.339, 0.579) when a=0.99 and b=0.01, and an emission chromaticity of (0.377, 0.570) when a=0.495 and b=0.01. Also, the Ce concentration contained in this poly crystal phosphor powder is several orders of magnitude higher than the Ce concentration contained in the single crystal phosphor of the present embodiment.

In this manner, in the single crystal phosphor, the Ce concentration to be added to emit light of a desired color is very low in comparison with the poly crystal phosphor, making it possible to reduce the amount of the expensive Ce to be used.

Below will be described one example of a method for producing the single crystal phosphor in the present embodiment. In the following example, the single crystal phosphor is grown by the Czochralski method (CZ method).

### [Production of the Single Crystal Phosphor]

First, as starting raw materials, high purity (99.99% or higher) powders of Y₂O₃, Lu₂O₃, Gd₂O₃, CeO₂, and Al₂O₃ are prepared, and dry mixed to produce a powder mixture. Incidentally, the raw material powders of Y, Lu, Gd, Ce, and Al are not limited to those described above. Further, when a single crystal phosphor containing no Lu or Gd is produced, no raw material powders thereof are used.

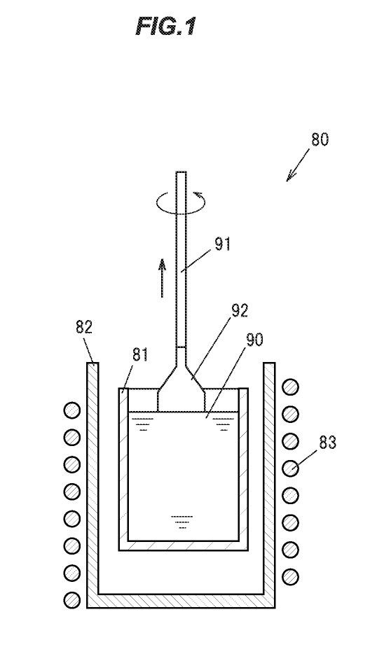

FIG. 1 is a cross sectional view schematically showing a pulling of a single crystal phosphor ingot by the CZ method. A crystal growing apparatus 80 mainly includes an iridium crucible 81, a ceramic cylindrical container 82 for containing the crucible 81, and a high-frequency coil 83 wound around the cylindrical container 82.

The resulting powder mixture is installed in the crucible 81, and a high frequency energy of 30 kW is fed by the high frequency coil 83 in a nitrogen atmosphere to the crucible 81 to induce current to heat the crucible 81. This melts the powder mixture to produce a melt 90.

Next, a seed crystal 91 that is the YAG single crystal is prepared, and its tip is brought into contact with the melt 90, and thereafter is rotated at a rotational speed of 10 rpm, while being pulled at a pulling speed of 1 mm/h or less, to grow a single crystal phosphor ingot 92 in the <111> direction at a pulling temperature of 1960 degrees C. or higher. The growth of the single crystal phosphor ingot 92 is conducted under atmospheric pressure, in the nitrogen atmosphere, by feeding the nitrogen into the cylindrical container at a flow rate of 2 L per minute.

This results in the single crystal phosphor ingot 92 of a diameter of about 2.5 cm, and a length of about 5 cm, for example. By cutting out the resulting single crystal phosphor ingot 92 to a desired size, a flat plate-shaped single crystal phosphor to be used in a light emitting device for example can be produced. Also, by pulverizing the single crystal phosphor ingot 92, it is possible to produce a particulate single crystal phosphor.

### [Evaluation of the Single Crystal Phosphor]

A plurality of single crystal phosphors having different compositions in the first embodiment were produced, and the analysis of the compositions, and the evaluation of CIE chromaticity, internal quantum efficiency, and external quantum efficiency were conducted.

The composition analysis was performed by high-frequency inductively coupled plasma (ICP) emission spectroscopy. Also, for single crystal phosphors having a very low Ce concentration, ICP mass spectrometry (ICP-MS) was used in combination.

In the evaluation of the CIE chromaticity coordinates, the CIE1931 color matching function was used, and the CIE chromaticity coordinates of emission spectra of the single crystal phosphors at an exciting light peak wavelength of 450 nm were determined.

The evaluations of the internal quantum efficiency and the external quantum efficiency were performed by using a quantum efficiency measuring system with an integrating hemisphere unit. Below are described specific methods for measuring the internal quantum efficiency and the external quantum efficiency of the single crystal phosphors.

First, by irradiating exciting light to a barium sulfate powder as a standard sample installed in the integrating hemisphere unit, an exciting light spectrum is measured. Then, by irradiating exciting light to a single crystal phosphor installed on the barium sulfate in the integrating hemisphere unit, a reflected exciting light spectrum and a fluorescence emission spectrum are measured. Then, by irradiating the exciting light diffuse reflected in the integrating hemisphere unit to the single crystal phosphor installed on the barium sulfate, a re-excited fluorescence emission spectrum is measured.

Then, by dividing a difference between a photon number obtained from the fluorescence emission spectrum and a photon number obtained from the re-excited fluorescence emission spectrum by a difference between a photon number obtained from the exciting light spectrum and a photon number obtained from the reflected exciting light spectrum, the internal quantum efficiency is determined.

Further, by dividing the difference between the photon number obtained from the fluorescence emission spectrum and the photon number obtained from the re-excited fluorescence emission spectrum by the photon number obtained from the exciting light spectrum, the external quantum efficiency is determined.

Evaluated results are shown in Tables 1 and 2 below. Table 1 shows the evaluated results of single crystal phosphor samples Nos. 1 to 23, and Table 2 shows the evaluated results of single crystal phosphor samples Nos. 24 to 46.

Tables 1 and 2 show x, y, z, and a values in the composition formula of the single crystal phosphor in the present embodiment, measurement temperatures (degrees C.) of the single crystal phosphors, internal quantum efficiencies (ηᵢₙₜ) at exciting light peak wavelengths of 440, 450, and 460 nm, ηᵢₙₜ (300 degrees C.)/ηᵢₙₜ (25 degrees C.) serving as a measure of temperature properties of the internal quantum efficiencies ηᵢₙₜ, external quantum efficiencies (ηₑₓₜ) at exciting light peak wavelengths of 440, 450, and 460 nm, ηₑₓₜ (300 degrees C.)/ηₑₓₜ (25 degrees C.) serving as a measure of temperature properties of the external quantum efficiencies ηₑₓₜ, fluorescence peak wavelengths λp (nm) at the exciting light peak wavelength of 450 nm, and CIE chromaticity coordinates at the exciting light peak wavelength of 450 nm.

Here, ηᵢₙₜ (300 degrees C.) is the internal quantum efficiency at the temperature of 300 degrees C. and the exciting light peak wavelength of 450 nm, ηᵢₙₜ (25 degrees C.) is the internal quantum efficiency at the temperature of 25 degrees C. and the exciting light peak wavelength of 450 nm, and ηᵢₙₜ (300 degrees C.)/ηᵢₙₜ (25 degrees C.) is the value of the ratio of ηᵢₙₜ (300 degrees C.) to ηᵢₙₜ (25 degrees C.). Further, ηₑₓₜ (300 degrees C.) is the external quantum efficiency at the temperature of 300 degrees C. and the exciting light peak wavelength of 450 nm, ηₑₓₜ (25 degrees C.) is the external quantum efficiency at the temperature of 25 degrees C. and the exciting light peak wavelength of 450 nm, and ηₑₓₜ (300 degrees C.)/ηₑₓₜ (25 degrees C.) is the value of the ratio of ηₑₓₜ (300 degrees C.) to ηₑₓₜ (25 degrees C.).

As to shapes of the samples of the evaluated single crystalline phosphors, Sample No. 2 was a circular plate of a diameter of 10 mm and a thickness of 1.0 mm, Samples Nos. 17 and 23 were circular plates of a diameter of 10 mm and a thickness of 0.3 mm, Sample No. 46 was powder, and the other samples were square plates of a one side length of 10 mm and a thickness of 0.3 mm. Also, all the samples except the powdered sample had both mirror polished surfaces.

Although the shapes of the samples in principle affect the measured values of the external quantum efficiencies, the values of the ratios of the external quantum efficiencies of the same samples, for example, the values of ηₑₓₜ (300 degrees C.)/ηₑₓₜ (25 degrees C.) do not depend on the shapes of the samples. On the other hand, the measured values of the internal quantum efficiencies are little affected by the shapes of the samples.

TABLE 1

| | | | | | | Internal quantum | | | ηᵢₙₜ | External quantum | | | ηₑₓₜ | | CIE | |
|---|---|---|---|---|---|---|---|---|---|---|---|---|---|---|---|---|
| | | | | | | efficiency(ηᵢₙₜ) | | | (300° C.)/ | efficiency(ηₑₓₜ) | | | (300° C.)/ | | chromaticity | |
| Sample | | | | | Temp | 440 | 450 | 460 | ηᵢₙₜ | 440 | 450 | 460 | ηₑₓₜ | λp | x | y |
| No. | x | y | z | a | [° C.] | nm | nm | nm | (25° C.) | nm | nm | nm | (25° C.) | [nm] | coord | coord |
| 1 | 0.2909 | 0.0000 | 0.0017 | 0.022 | 25 | 0.98 | 0.98 | 0.97 | — | 0.77 | 0.80 | 0.79 | — | 537 | 0.411 | 0.567 |
| 2 | 0.0000 | 0.0066 | 0.0013 | 0.024 | 25 | 0.99 | 0.97 | 0.98 | — | 0.81 | 0.80 | 0.80 | — | 543 | 0.426 | 0.557 |
| 3 | 0.2785 | 0.0073 | 0.0017 | 0.024 | 25 | 0.97 | 0.96 | 0.96 | — | 0.74 | 0.76 | 0.77 | — | 543 | 0.414 | 0.564 |
| 4 | 0.9994 | 0.0000 | 0.0006 | 0.023 | 25 | 1.00 | 0.99 | 0.97 | 1.00 | 0.61 | 0.62 | 0.55 | 0.87 | 514 | 0.329 | 0.600 |
| | | | | | 100 | 0.96 | 0.96 | 0.96 | | 0.57 | 0.60 | 0.53 | | 520 | 0.335 | 0.601 |
| | | | | | 150 | 0.97 | 0.96 | 0.96 | | 0.56 | 0.58 | 0.51 | | 527 | 0.341 | 0.600 |
| | | | | | 200 | 0.98 | 0.99 | 1.00 | | 0.54 | 0.54 | 0.50 | | 527 | 0.346 | 0.598 |
| | | | | | 250 | 1.00 | 1.00 | 1.00 | | 0.53 | 0.54 | 0.50 | | 530 | 0.350 | 0.596 |
| | | | | | 300 | 0.98 | 0.99 | 0.96 | | 0.52 | 0.54 | 0.50 | | 530 | 0.356 | 0.592 |
| 5 | 0.0000 | 0.0000 | 0.0013 | 0.000 | 25 | 1.00 | 0.99 | 0.96 | — | 0.57 | 0.67 | 0.67 | 1.00 | 539 | 0.415 | 0.562 |
| 6 | 0.0000 | 0.0000 | 0.0047 | 0.005 | 25 | 0.99 | 0.98 | 0.98 | — | 0.70 | 0.77 | 0.78 | 1.00 | 540 | 0.421 | 0.559 |
| 7 | 0.0000 | 0.0000 | 0.0067 | −0.010 | 25 | 1.00 | 1.00 | 1.00 | 0.92 | 0.80 | 0.81 | 0.82 | 0.91 | 544 | 0.434 | 0.551 |
| | | | | | 100 | 1.02 | 1.00 | 0.98 | | 0.81 | 0.81 | 0.80 | | 550 | 0.442 | 0.544 |
| | | | | | 150 | 1.01 | 0.99 | 0.98 | | 0.81 | 0.81 | 0.80 | | 553 | 0.449 | 0.539 |
| | | | | | 200 | 1.00 | 0.99 | 0.97 | | 0.80 | 0.80 | 0.79 | | 555 | 0.455 | 0.533 |
| | | | | | 250 | 0.99 | 0.97 | 0.95 | | 0.78 | 0.78 | 0.77 | | 560 | 0.462 | 0.526 |
| | | | | | 300 | 0.93 | 0.92 | 0.91 | | 0.74 | 0.74 | 0.73 | | 564 | 0.468 | 0.520 |
| 8 | 0.0000 | 0.0000 | 0.0014 | 0.175 | 25 | 0.99 | 0.98 | 0.99 | 0.96 | 0.76 | 0.78 | 0.79 | 0.94 | 544 | 0.425 | 0.557 |
| | | | | | 300 | 0.95 | 0.94 | 0.94 | | 0.70 | 0.73 | 0.73 | | 564 | 0.463 | 0.524 |
| 9 | 0.0000 | 0.0000 | 0.0014 | 0.228 | 25 | 1.00 | 0.98 | 0.99 | — | 0.78 | 0.80 | 0.81 | — | 542 | 0.424 | 0.558 |
| 10 | 0.0000 | 0.0000 | 0.0014 | 0.167 | 25 | 0.99 | 0.97 | 0.98 | — | 0.77 | 0.78 | 0.80 | — | 540 | 0.426 | 0.557 |
| 11 | 0.0000 | 0.0000 | 0.0002 | 0.137 | 25 | 0.95 | 0.96 | 0.95 | — | 0.27 | 0.36 | 0.37 | — | 531 | 0.405 | 0.564 |
| 12 | 0.0000 | 0.0000 | 0.0002 | 0.190 | 25 | 0.96 | 1.00 | 0.96 | — | 0.30 | 0.41 | 0.41 | — | 530 | 0.405 | 0.564 |
| 13 | 0.0000 | 0.0000 | 0.0005 | 0.054 | 25 | 0.95 | 0.99 | 0.94 | — | 0.45 | 0.59 | 0.58 | — | 533 | 0.412 | 0.563 |
| 14 | 0.0000 | 0.0000 | 0.0010 | 0.128 | 25 | 0.97 | 0.96 | 0.96 | — | 0.70 | 0.76 | 0.77 | — | 537 | 0.420 | 0.560 |
| 15 | 0.0222 | 0.0000 | 0.0013 | 0.021 | 25 | 1.00 | 0.99 | 0.96 | — | 0.55 | 0.65 | 0.64 | — | 531 | 0.408 | 0.566 |
| 16 | 0.0905 | 0.0000 | 0.0013 | −0.016 | 25 | 1.00 | 0.96 | 0.96 | — | 0.64 | 0.70 | 0.72 | — | 536 | 0.415 | 0.562 |
| 17 | 0.1133 | 0.0000 | 0.0013 | 0.002 | 25 | 0.98 | 0.97 | 0.95 | — | 0.56 | 0.65 | 0.65 | — | 531 | 0.406 | 0.567 |
| 18 | 0.1436 | 0.0000 | 0.0014 | −0.006 | 25 | 0.99 | 0.96 | 0.98 | — | 0.63 | 0.70 | 0.72 | — | 530 | 0.407 | 0.567 |
| 19 | 0.2735 | 0.0000 | 0.0006 | 0.036 | 25 | 0.94 | 0.98 | 0.96 | — | 0.53 | 0.61 | 0.60 | — | 528 | 0.397 | 0.572 |
| 20 | 0.5301 | 0.0000 | 0.0009 | 0.047 | 25 | 0.97 | 0.96 | 0.96 | — | 0.65 | 0.68 | 0.67 | — | 528 | 0.384 | 0.581 |
| 21 | 0.0000 | 0.0330 | 0.0020 | 0.030 | 25 | 0.96 | 0.99 | 0.98 | — | 0.75 | 0.80 | 0.80 | — | 543 | 0.434 | 0.550 |
| 22 | 0.0000 | 0.0669 | 0.0010 | 0.139 | 25 | 0.98 | 0.96 | 0.98 | — | 0.73 | 0.79 | 0.83 | — | 545 | 0.433 | 0.551 |
| 23 | 0.2324 | 0.0000 | 0.0002 | 0.140 | 25 | 0.91 | 0.91 | 0.95 | — | 0.37 | 0.79 | 0.83 | — | 525 | 0.390 | 0.571 |

TABLE 2

| | | | | | | Internal quantum | | | ηᵢₙₜ | External quantum | | | ηₑₓₜ | | CIE | |
|---|---|---|---|---|---|---|---|---|---|---|---|---|---|---|---|---|
| | | | | | | efficiency(ηᵢₙₜ) | | | (300° C.)/ | efficiency(ηₑₓₜ) | | | (300° C.)/ | | chromaticity | |
| Sample | | | | | Temp | 440 | 450 | 460 | ηᵢₙₜ | 440 | 450 | 460 | ηₑₓₜ | λp | x | y |
| No. | x | y | z | a | [° C.] | nm | nm | nm | (25° C.) | nm | nm | nm | (25° C.) | [nm] | coord | coord |
| 24 | 0.2239 | 0.0000 | 0.0002 | 0.170 | 25 | 0.93 | 0.98 | 0.95 | — | 0.37 | 0.79 | 0.83 | — | 531 | 0.389 | 0.569 |
| 25 | 0.2183 | 0.0000 | 0.0002 | 0.161 | 25 | 0.99 | 0.96 | 0.97 | — | 0.42 | 0.79 | 0.83 | — | 533 | 0.389 | 0.569 |
| 26 | 0.1955 | 0.0000 | 0.0003 | 0.315 | 25 | 0.93 | 0.94 | 0.94 | — | 0.46 | 0.79 | 0.83 | — | 531 | 0.396 | 0.571 |
| 27 | 0.1892 | 0.0000 | 0.0008 | 0.112 | 25 | 0.96 | 0.96 | 0.96 | — | 0.65 | 0.79 | 0.83 | — | 532 | 0.406 | 0.568 |
| 28 | 0.2298 | 0.0000 | 0.0004 | 0.158 | 25 | 0.93 | 0.96 | 0.96 | — | 0.56 | 0.66 | 0.66 | — | 529 | 0.401 | 0.571 |
| 29 | 0.2099 | 0.0000 | 0.0006 | 0.216 | 25 | 0.98 | 0.94 | 0.96 | — | 0.66 | 0.71 | 0.72 | — | 531 | 0.406 | 0.569 |
| 30 | 0.1886 | 0.0000 | 0.0011 | 0.251 | 25 | 0.98 | 1.00 | 0.97 | 0.96 | 0.75 | 0.80 | 0.78 | 0.91 | 539 | 0.413 | 0.565 |
| | | | | | 100 | 1.00 | 1.00 | 0.99 | | 0.75 | 0.80 | 0.78 | | 545 | 0.424 | 0.557 |
| | | | | | 150 | 1.00 | 1.00 | 0.99 | | 0.75 | 0.78 | 0.77 | | 549 | 0.430 | 0.552 |
| | | | | | 200 | 0.99 | 1.00 | 0.97 | | 0.74 | 0.79 | 0.75 | | 551 | 0.437 | 0.546 |
| | | | | | 250 | 1.00 | 0.98 | 0.98 | | 0.72 | 0.74 | 0.73 | | 554 | 0.444 | 0.539 |
| | | | | | 300 | 0.93 | 0.96 | 0.91 | | 0.67 | 0.73 | 0.69 | | 559 | 0.451 | 0.533 |
| 31 | 0.2932 | 0.0000 | 0.0006 | 0.152 | 25 | 0.96 | 0.95 | 0.96 | — | 0.67 | 0.72 | 0.72 | — | 531 | 0.402 | 0.571 |
| 32 | 0.2821 | 0.0000 | 0.0009 | 0.158 | 25 | 0.98 | 0.99 | 0.99 | — | 0.73 | 0.78 | 0.78 | — | 533 | 0.406 | 0.570 |
| 33 | 0.2597 | 0.0000 | 0.0014 | 0.168 | 25 | 0.99 | 0.99 | 0.99 | — | 0.79 | 0.81 | 0.81 | — | 539 | 0.413 | 0.566 |
| 34 | 0.3528 | 0.0000 | 0.0009 | 0.177 | 25 | 0.98 | 0.95 | 0.96 | — | 0.74 | 0.76 | 0.77 | — | 531 | 0.400 | 0.573 |
| 35 | 0.3357 | 0.0000 | 0.0012 | 0.145 | 25 | 0.99 | 0.98 | 0.95 | — | 0.76 | 0.81 | 0.80 | — | 540 | 0.405 | 0.571 |
| 36 | 0.3109 | 0.0000 | 0.0021 | 0.130 | 25 | 0.98 | 0.98 | 0.96 | — | 0.78 | 0.81 | 0.84 | — | 543 | 0.417 | 0.564 |
| 37 | 0.0000 | 0.0048 | 0.0008 | 0.225 | 25 | 0.96 | 0.97 | 0.97 | — | 0.67 | 0.75 | 0.76 | — | 540 | 0.420 | 0.560 |
| 38 | 0.0000 | 0.0055 | 0.0011 | 0.196 | 25 | 0.99 | 0.97 | 0.97 | — | 0.70 | 0.76 | 0.77 | — | 541 | 0.422 | 0.558 |
| 39 | 0.0000 | 0.0066 | 0.0015 | 0.143 | 25 | 0.99 | 0.96 | 0.96 | — | 0.77 | 0.79 | 0.79 | — | 543 | 0.427 | 0.555 |
| 40 | 0.0000 | 0.0102 | 0.0011 | 0.146 | 25 | 0.97 | 0.95 | 0.98 | — | 0.71 | 0.76 | 0.78 | — | 543 | 0.426 | 0.556 |
| 41 | 0.0000 | 0.0105 | 0.0012 | 0.156 | 25 | 0.97 | 0.96 | 0.99 | — | 0.73 | 0.77 | 0.80 | — | 544 | 0.428 | 0.555 |
| 42 | 0.0000 | 0.0134 | 0.0021 | 0.127 | 25 | 0.97 | 0.97 | 0.98 | — | 0.78 | 0.81 | 0.84 | — | 544 | 0.434 | 0.551 |
| 43 | 0.0000 | 0.0213 | 0.0001 | 0.159 | 25 | 0.99 | 1.00 | 0.97 | — | 0.74 | 0.80 | 0.79 | — | 543 | 0.428 | 0.554 |
| 44 | 0.0000 | 0.0236 | 0.0013 | 0.186 | 25 | 0.99 | 0.99 | 0.99 | — | 0.77 | 0.81 | 0.81 | — | 545 | 0.431 | 0.552 |
| 45 | 0.0000 | 0.0302 | 0.0024 | 0.144 | 25 | 0.98 | 0.99 | 0.99 | 0.82 | 0.80 | 0.82 | 0.82 | 0.80 | 546 | 0.441 | 0.546 |
| | | | | | 100 | 0.98 | 0.98 | 0.98 | | 0.80 | 0.82 | 0.81 | | 554 | 0.452 | 0.536 |
| | | | | | 150 | 0.98 | 0.99 | 0.99 | | 0.80 | 0.81 | 0.81 | | 561 | 0.461 | 0.528 |
| | | | | | 200 | 0.98 | 0.98 | 0.98 | | 0.79 | 0.81 | 0.81 | | 564 | 0.468 | 0.521 |
| | | | | | 250 | 0.93 | 0.94 | 0.93 | | 0.74 | 0.76 | 0.76 | | 568 | 0.476 | 0.514 |
| | | | | | 300 | 0.80 | 0.81 | 0.80 | | 0.64 | 0.66 | 0.65 | | 570 | 0.482 | 0.507 |
| 46 | 0.3357 | 0.0000 | 0.0012 | 0.145 | 25 | 0.94 | 0.94 | 0.94 | 0.97 | 0.57 | 0.61 | 0.60 | 0.88 | 527 | 0.387 | 0.571 |
| | | | | | 300 | 0.92 | 0.91 | 0.92 | | 0.52 | 0.53 | 0.52 | | 550 | 0.405 | 0.557 |

According to Table 1, the compositions of the samples of the evaluated single crystal phosphors were included in the composition represented by the composition formula (Y_{1-x-y-z}LuₓGd_{y}Ce_{z})₃₊ₐAl₅₋ₐO₁₂(0≦x≦0.9994, 0≦y≦0.0669, 0.0002≦z≦0.0067, −0.016≦a≦0.315).

According to Table 1, the internal quantum efficiencies at the temperature of 25 degrees C. and the exciting light peak wavelength of 450 nm of all the samples of the single crystalline phosphors evaluated were not lower than 0.91.

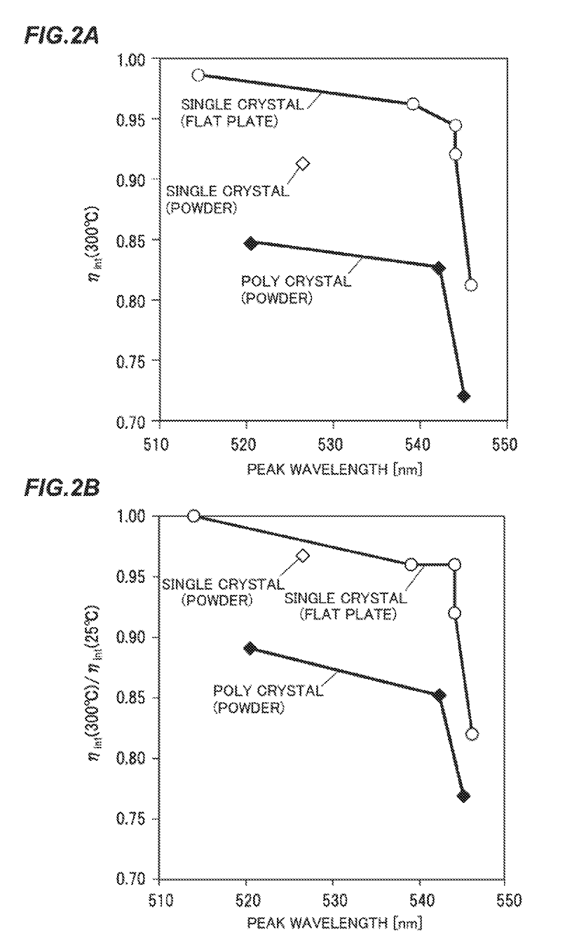

FIG. 2A is a graph showing relationships between the fluorescence peak wavelength (nm) at a temperature of 25 degrees C. and an exciting light peak wavelength of 450 nm and the internal quantum efficiency ηᵢₙₜ (300 degrees C.), of the single crystal phosphors in the present embodiment. Further, FIG. 2B is a graph showing relationships between the fluorescence peak wavelength (nm) at a temperature of 25 degrees C. and an exciting light peak wavelength of 450 nm, and the value of the internal quantum efficiency ratio, ηᵢₙₜ (300 degrees C.)/ηᵢₙₜ (25 degrees C.), of the single crystal phosphors in the present embodiment.

In FIGS. 2A and 2B, the marks “◯” are the measured values for the flat plate-shaped single crystal phosphors (samples Nos. 4, 7, 8, 30, and 45) in the present embodiment, the mark “⋄” is the measured value for the powdery single crystal phosphor (sample No. 46), and the marks “♦” are the measured values for YAG based poly crystal phosphor powders activated by Ce as comparative examples.

According to FIG. 2A, the internal quantum efficiencies ηᵢₙₜ (300 degrees C.) of the single crystal phosphors in the present embodiment were not lower than 0.90 in the samples whose fluorescence peak wavelength was not shorter than 514 nm and not longer than 544 nm at the temperature of 25 degrees C. and the exciting light peak wavelength of 450 nm, and were not lower than 0.80 in the samples whose fluorescence peak wavelength was longer than 544 nm and not longer than 546 nm at the temperature of 25 degrees C. and the exciting light peak wavelength of 450 nm.

Further, according to FIG. 2A, the internal quantum efficiencies ηᵢₙₜ (300 degrees C.) of the poly crystal phosphors were lower than the internal quantum efficiencies ηᵢₙₜ (300 degrees C.) of the single crystal phosphors in the present embodiment, and fell below 0.85 in the samples whose fluorescence peak wavelength was not shorter than 514 nm and not longer than 544 nm at the temperature of 25 degrees C. and the exciting light peak wavelength of 450 nm, and fell below 0.75 in the samples whose fluorescence peak wavelength was longer than 544 nm and not longer than 546 nm at the temperature of 25 degrees C. and the exciting light peak wavelength of 450 nm.

According to FIG. 2B, the values of the internal quantum efficiency ratios of the single crystal phosphors in the present embodiment, ηᵢₙₜ (300 degrees C.)/ηᵢₙₜ (25 degrees C.) were not lower than 0.90 in the samples whose fluorescence peak wavelength was not shorter than 514 nm and not longer than 544 nm at the temperature of 25 degrees C. and the exciting light peak wavelength of 450 nm, and were not lower than 0.80 in the samples whose fluorescence peak wavelength was longer than 544 nm and not longer than 546 nm at the temperature of 25 degrees C. and the exciting light peak wavelength of 450 nm.

Further, according to FIG. 2B, the values of the internal quantum efficiency ratios of the poly crystal phosphors, ηᵢₙₜ(300 degrees C.)/ηᵢₙₜ(25 degrees C.) were lower than the values of the internal quantum efficiency ratios of the single crystal phosphors in the present embodiment, ηᵢₙₜ(300 degrees C.)/ηᵢₙₜ (25 degrees C.), and fell below 0.90 in the samples whose fluorescence peak wavelength was not shorter than 514 nm and not longer than 544 nm at the temperature of 25 degrees C. and the exciting light peak wavelength of 450 nm, and fell below 0.80 in the samples whose fluorescence peak wavelength was longer than 544 nm and not longer than 546 nm at the temperature of 25 degrees C. and the exciting light peak wavelength of 450 nm.

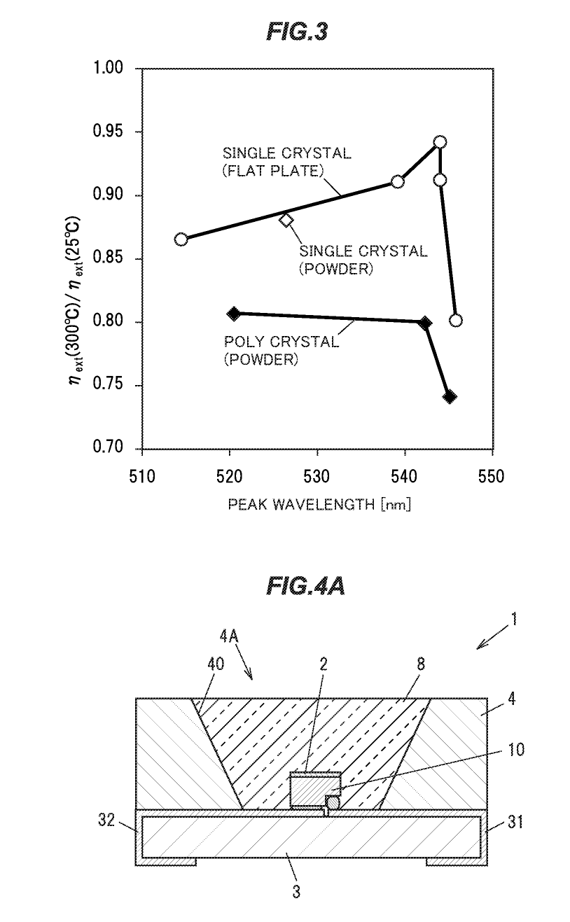

FIG. 3 is a graph showing relationships between the fluorescence peak wavelength (nm) at a temperature of 25 degrees C. and an exciting light peak wavelength of 450 nm and the value of the external quantum efficiency ratio, ηₑₓₜ (300 degrees C.)/ηₑₓₜ (25 degrees C.), of the single crystal phosphor in the present embodiment.

In FIG. 3, the marks “◯” are the measured values for the flat plate-shaped single crystal phosphors (samples Nos. 4, 7, 8, 30, and 45) in the present embodiment, the mark “⋄” is the measured value for the powdery single crystal phosphor (sample No. 46), and the marks “♦” are the measured values for the YAG based poly crystal phosphor powders activated by Ce as the comparative examples.

According to FIG. 3, the values of the external quantum efficiency ratios of the single crystal phosphors in the present embodiment, ηₑₓₜ (300 degrees C.)/ηₑₓₜ (25 degrees C.) were not lower than 0.85 in the samples whose fluorescence peak wavelength was not shorter than 514 nm and not longer than 544 nm at the temperature of 25 degrees C. and the exciting light peak wavelength of 450 nm, and were not lower than 0.80 in the samples whose fluorescence peak wavelength was longer than 544 nm and not longer than 546 nm at the temperature of 25 degrees C. and the exciting light peak wavelength of 450 nm.

According to FIG. 3, the values of the external quantum efficiency ratios of the poly crystal phosphors, ηₑₓₜ (300 degrees C.)/ηₑₓₜ (25 degrees C.) were lower than the values of the external quantum efficiency ratios of the single crystal phosphors in the present embodiment, ηₑₓₜ (300 degrees C.)/ηₑₓₜ (25 degrees C.), and fell below 0.85 in the samples whose fluorescence peak wavelength was not shorter than 514 nm and not longer than 544 nm at the temperature of 25 degrees C. and the exciting light peak wavelength of 450 nm, and fell below 0.75 in the samples whose fluorescence peak wavelength was longer than 544 nm and not longer than 546 nm at the temperature of 25 degrees C. and the exciting light peak wavelength of 450 nm.

### Second Embodiment

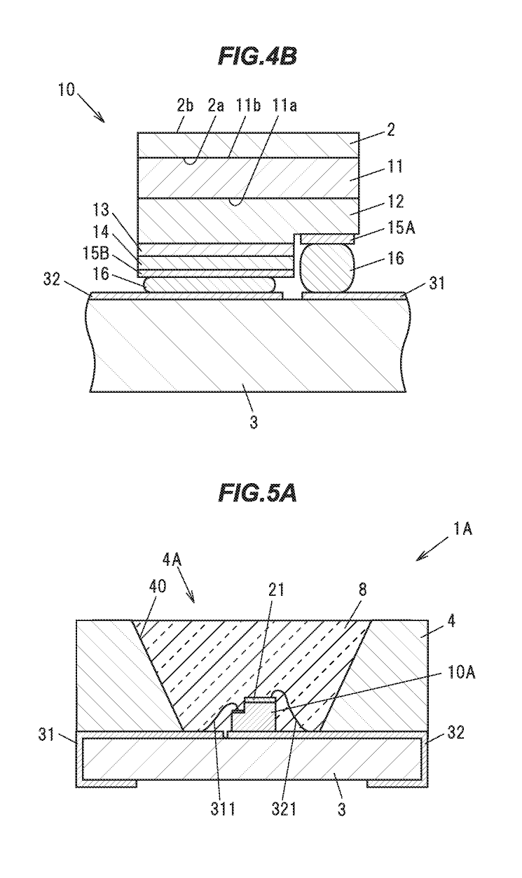

A second embodiment of the present invention relates to a light emitting device using a single crystal phosphor in the first embodiment. Hereinafter, the second embodiment will be described with reference to FIG. 4A. FIG. 4A is a vertical cross sectional view showing a light emitting device 1 in the second embodiment, while FIG. 4B is a vertical cross sectional view showing a light emitting element 10 constituting that light emitting device 1 and its peripheral portion.

As shown in FIG. 4A, the light emitting device 1 includes a light emitting element 10, such as an LED (light emitting diode), a phosphor 2 made of the single crystal phosphor in the first embodiment, which is provided in such a manner as to cover a light emitting surface of the light emitting element 10, a ceramic substrate 3 made of Al₂O₃ or the like for supporting the light emitting element 10, a body 4 made of a white resin, and a transparent resin 8 for sealing the light emitting element 10 and the phosphor 2.

The ceramic substrate 3 has wiring sections 31 and 32, which are pattern formed from a metal, such as tungsten or the like. The wiring sections 31 and 32 are electrically connected to an n-side electrode 15A and a p-side electrode 15B, respectively, of the light emitting element 10.

The body 4 is formed on the ceramic substrate 3, and is formed with an opening 4A through the middle thereof. The opening 4A is formed in a tapered shape whose opening width gradually increases outward from the ceramic substrate 3 side. The inner surface of the opening 4A is formed as a reflecting surface 40 to reflect light emitted from the light emitting element 10 outward.

As shown in FIG. 4B, the n-side electrode 15A and the p-side electrode 15B of the light emitting element 10 are connected via bumps 16 to the wiring sections 31 and 32 of the ceramic substrate 3, respectively.

The light emitting element 10 is, for example, a flip chip element using a GaN based semiconductor compound, and is designed to emit bluish light having a peak light intensity at a wavelength of 380 to 490 nm, for example. This light emitting element 10 is in turn formed with an n-type GaN layer 12, a light emitting layer 13, and a p-type GaN layer 14 on a first principal plane 11a of an element substrate 11 made of sapphire or the like. On an exposed portion of the n-type GaN layer 12 is formed the n-side electrode 15A, while over a surface of the p-type GaN layer 14 is formed the p-side electrode 15B.

The light emitting layer 13 is designed in such a manner that carriers are injected from the n-type GaN layer 12 and the p-type GaN layer 14 to thereby emit bluish light. This emitted light is transmitted through the n-type GaN layer 12 and the element substrate 11 and is emitted from a second principal plane 11b of the element substrate 11. In other words, the second principal plane 11b of the element substrate 11 is the light emitting surface of the light emitting element 10.

On the second principal plane 11b side of the element substrate 11, the phosphor 2 is installed in such a manner as to cover the entire second principal plane 11b. For example, when the phosphor 2 and the element substrate 11 are in direct contact, a first surface 2a of the phosphor 2, which is located opposite the element substrate 11, and the second principal plane 11b of the element substrate 11 are joined by intermolecular force.

The phosphor 2 is a plate-shaped single crystal phosphor. The plate-shaped single crystal phosphor does not need to be dispersed in the resin unlike particulate phosphor, therefore there are no problems such as variations, etc. in emission color caused by degradation of the resin due to light or heat. For this reason, light emitting devices using the plate-shaped single crystal phosphor such as the light emitting device 1 have very high long-term reliability under conditions of high intensity, high power, high temperatures, etc. The phosphor 2 is equal or larger in size than the second principal plane 11b.

When the light emitting element 10 configured as described above is energized, electrons are injected through the wiring section 31, the n-side electrode 15A, and the n-type GaN layer 12 into the light emitting layer 13, while holes are injected through the wiring section 32, the p-side electrode 15B, and the p-type GaN layer 14 into the light emitting layer 13, resulting in light emission of the light emitting layer 13. The blue light emitted by the light emitting layer 13 is transmitted through the n-type GaN layer 12 and the element substrate 11, is emitted from the second principal plane 11b of the element substrate 11, and is incident on the first surface 2a of the phosphor 2.

Some of the light passed through the first surface 2a acts as exciting light to excite an electron in the phosphor 2. The phosphor 2 absorbs some of the bluish light from the light emitting element 10, and wavelength converts into yellowish light having a peak light intensity at a wavelength of 514 to 546 nm for example.

Some of the bluish light passed into the phosphor 2 is absorbed into the phosphor 2, wavelength converted, and emitted from the second surface 2b of the phosphor 2 as yellowish light, while the remaining of the light passed into the phosphor 2 is emitted from the second surface 2b of the phosphor 2 without being absorbed into the phosphor 2. Since the blue color and the yellow color are complementary to each other, the light emitting device 1 emits white light with the blue light and the yellow light mixed together therein.

Further, the color temperature of the white light to be emitted by the light emitting device 1 can be set at 4500 K or higher. The color temperature of the white light can be adjusted according to the concentration of Lu or Gd in the phosphor 2, or the concentration of Ce acting as an activator, and the like. Further, by the addition of a second phosphor having a longer wavelength fluorescence spectrum than the phosphor 2, it is possible to adjust the color temperature of the white light to be emitted by the light emitting device 1 to lower than 4500 K.

### Third Embodiment

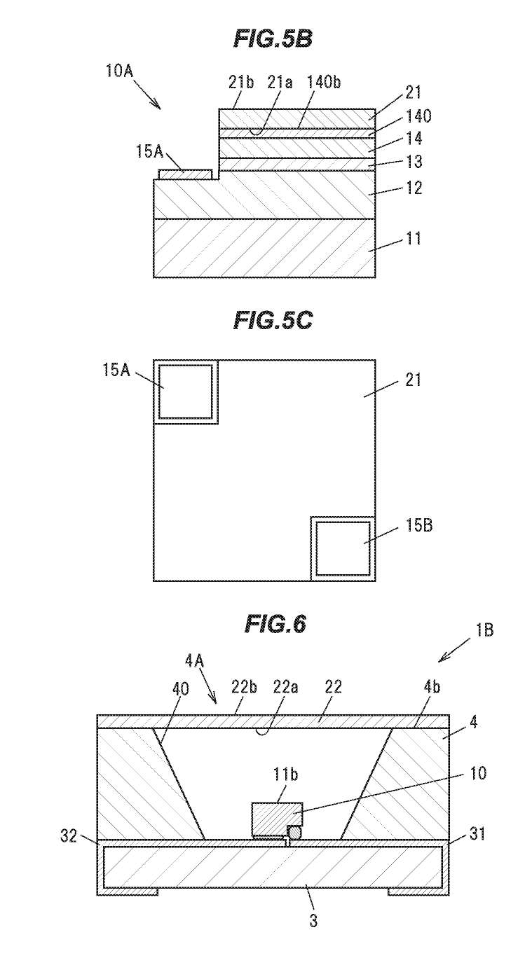

Next, a third embodiment of the present invention will be described with reference to FIGS. 5A to 5C. FIG. 5A is a vertical cross sectional view showing a light emitting device 1A in the third embodiment, FIG. 5B is a vertical cross sectional view showing a light emitting element 10A constituting that light emitting device 1A, and FIG. 5C is a plan view showing a light emitting element 10A.

The light emitting device 1A in the present embodiment is configured in the same manner as the light emitting device 1 in the second embodiment in that light emitted by its light emitting element is passed into its single crystal phosphor and wavelength converted, but differs from the second embodiment in the configuration of its light emitting element and the arrangement location of its phosphor relative to its light emitting element. Hereinafter, constituent elements of the light emitting device 1A having the same functions and configurations as those of the second embodiment will be given common reference characters, and descriptions thereof will be omitted.

As shown in FIGS. 5A and 5B, the light emitting device 1A is disposed in such a manner that an element substrate 11 of a light emitting element 10A faces a ceramic substrate 3 side. Further, a phosphor 21 is joined to an opening 4A side of the light emitting element 10A. The phosphor 21, as with the phosphor 2 in the second embodiment, is made of the single crystal phosphor in the first embodiment.

As shown in FIGS. 5B and 5C, the light emitting element 10A includes an element substrate 11, an n-type GaN layer 12, a light emitting layer. 13, and a p-type GaN layer 14, and further includes a transparent electrode 140 made of ITO (indium tin oxide: indium tin oxide) on the p-type GaN layer 14. The transparent electrode 140 is formed with a p-side electrode 15B thereon. The transparent electrode 140 is designed to diffuse carriers injected from the p-side electrode 15B and inject them into the p-type GaN layer 14.

As shown in FIG. 5C, the phosphor 21 is formed in a substantially rectangular shape having cutouts on portions corresponding to the p-side electrode 15B, and an n-side electrode 15A, respectively, to be formed on the n-type GaN layer 12. Further, the phosphor 21 has a first surface 21a on the transparent electrode 140 side, which is joined by intermolecular force to a surface 140b of the transparent electrode 140.

As shown in FIG. 5A, the n-side electrode 15A of the light emitting element 10A is connected to a wiring section 31 of the ceramic substrate 3 by a bonding wire 311. Further, the p-side electrode 15B of the light emitting element 10A is connected to a wiring section 32 of the ceramic substrate 3 by a bonding wire 321.

When the light emitting element 10A configured as described above is energized, electrons are injected through the wiring section 31, the n-side electrode 15A, and the n-type GaN layer 12 into the light emitting layer 13, while holes are injected through the wiring section 32, the p-side electrode 15B, the transparent electrode 140, and the p-type GaN layer 14 into the light emitting layer 13, resulting in light emission of the light emitting layer 13.

The blue light emitted by the light emitting layer 13 is transmitted through the p-type GaN layer 14 and the transparent electrode 140, and is emitted from the surface 140b of the transparent electrode 140. In other words, the surface 140b of the transparent electrode 140 is the light emitting surface of the light emitting element 10A. The light emitted from the surface 140b of the transparent electrode 140 is incident on the first surface 21a of the phosphor 21.

Some of the light passed through the first surface 21a into the phosphor 21 acts as exciting light to excite an electron in the phosphor 21. The phosphor 21 absorbs some of the blue light from the light emitting element 10A, and wavelength converts into yellow light. More specifically, the phosphor 21 absorbs the bluish light from the light emitting element 10A, and emits yellowish light having an emission peak at a wavelength of 514 to 546 nm for example.

In this manner, some of the blue light passed into the phosphor 21 is absorbed into the phosphor 21, wavelength converted, and emitted from the second surface 21b of the phosphor 21 as yellow light, while the remaining of the blue light passed into the phosphor 21 is emitted from the second surface 21b of the phosphor 21 without being absorbed into the phosphor 21. Since the blue color and the yellow color are complementary to each other, the light emitting device 1A emits white light with the blue light and the yellow light mixed together therein.

### Fourth Embodiment

Next, a fourth embodiment of the present invention will be described with reference to FIG. 6. FIG. 6 is a vertical cross sectional view showing a light emitting device 1B in the fourth embodiment.

The light emitting device 1B of the present embodiment is configured in the same manner as the light emitting device 1 in the second embodiment in that light emitted by its light emitting element is passed into its single crystal phosphor and wavelength converted, but differs from the second embodiment in the arrangement location of its phosphor. Hereinafter, constituent elements of the light emitting device 1B having the same functions and configurations as those of the second or the third embodiment will be given common reference characters, and descriptions thereof will be omitted.

As shown in FIG. 6, the light emitting apparatus 1B includes a light emitting element 10 configured in the same manner as in the second embodiment on a ceramic substrate 3. The light emitting element 10 is designed to emit blue light from a second principal plane 11b of an element substrate 11 (FIG. 4B) located on an opening 4A side of a body 4 toward the opening 4A side of the body 4.

A phosphor 22 is joined to the body 4 such that it covers the opening 4A of the body 4. The phosphor 22 is formed in a flat plate shape, and is joined by an adhesive or the like to an upper surface 4b of the body 4. The phosphor 22, as with the phosphor 2 in the second embodiment, is made of the single crystal phosphor in the first embodiment. Further, the phosphor 22 is larger than the light emitting element 10.

When the light emitting device 1B configured as described above is energized, the light emitting element 10 emits blue light from the second principal plane 11b toward the phosphor 22. The phosphor 22 absorbs the blue light emitted by the light emitting element 10 from a first surface 22a facing the emitting surface of the light emitting element 10, and radiates yellow fluorescence from a second surface 22b to the outside.

In this manner, some of the blue light passed into the phosphor 22 is absorbed into the phosphor 22, wavelength converted, and emitted from the second surface 22b of the phosphor 22 as yellow light, while the remaining of the blue light passed into the phosphor 22 is emitted from the second surface 22b of the phosphor 22 without being absorbed into the phosphor 22. Since the blue color and the yellow color are complementary to each other, the light emitting device 1B emits white light with the blue light and the yellow light mixed together therein.

In the present embodiment, since the light emitting element 10 and the phosphor 22 are spaced apart, as compared with when the phosphor is joined to the emitting surface of the light emitting element 10, it is possible to use the large-size phosphor 22, thereby enhancing ease of assembly of the light emitting device 1B.

### Fifth Embodiment

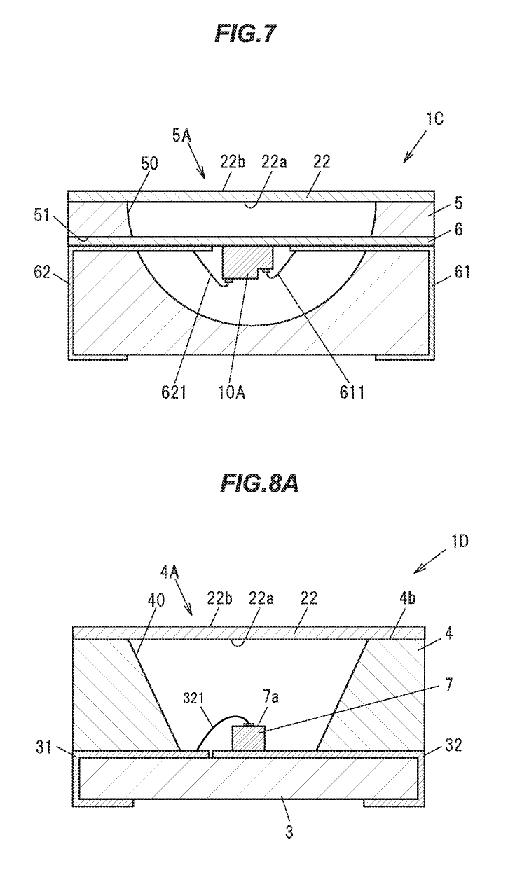

Next, a fifth embodiment of the present invention will be described with reference to FIG. 7. FIG. 7 is a cross sectional view showing a light emitting device 1C in the fifth embodiment. As shown in FIG. 7, the present embodiment differs from the fourth embodiment in the locational relationship between its light emitting element, and its substrate mounted with its light emitting element thereon and its phosphor. Hereinafter, constituent elements of the light emitting device 1C having the same functions and configurations as those of the second, the third or the fourth embodiment will be given common reference characters, and descriptions thereof will be omitted.

The light emitting device 1C in the present embodiment includes a body 5 made of a white resin, a transparent substrate 6, which is held in a slit-shaped holding portion 51 formed in the body 5, a phosphor 22, which is arranged in such a manner as to cover an opening 5A on the body 5, a light emitting element 10A, which is mounted on the opposite surface of the transparent substrate 6 to the phosphor 22 side surface thereof, wiring sections 61 and 62 for energizing the light emitting element 10A. The phosphor 22, as with the phosphor 2 in the second embodiment, is made of the single crystal phosphor in the first embodiment.

The body 5 is formed with a hemispherical concave portion at its center, and the surface of that concave portion is formed as a reflecting surface 50 to reflect light emitted by the light emitting element 10A to the phosphor 22 side.

The transparent substrate 6 is made of a translucent resin such as a silicone resin, an acrylic resin, a PET (polyethylene terephthalate), or like, or a translucent member made of a single crystal or a poly crystal such as a glassy material, a sapphire, a ceramic, a quartz, or like, and has a translucency allowing light emitted by the light emitting element 10A to pass therethrough and an electrical insulating property. Further, the transparent substrate 6 is being joined to respective portions of the wiring sections 61 and 62. A p-side electrode and an n-side electrode of the light emitting element 10A are being electrically connected to respective one ends of the wiring sections 61 and 62 via bonding wires 611 and 621, respectively. The respective other ends of the wiring sections 61 and 62 are being drawn out from the body 5.

When the light emitting device 1C configured as described above is energized, the light emitting element 10A emits light in such a manner that some of the light emitted is transmitted through the transparent substrate 6 and is incident on a first surface 22a of the phosphor 22, while the other of the light emitted is reflected off a reflecting surface 50 of the body 5, is transmitted through the transparent substrate 6 and is incident on the first surface 22a of the phosphor 22.

Some of the light passed into the phosphor 22 is absorbed into the phosphor 22, and wavelength converted, while the remaining of the light passed into the phosphor 22 is emitted from a second surface 22b of the phosphor 22 without being absorbed into the phosphor 22. In this manner, the light emitting device 1C mixes the blue light emitted by the light emitting element 10A and the yellow light wavelength converted by the phosphor 22 together to emit white light.

With the present embodiment, the light emitted from the light emitting element 10A to the opposite side to the phosphor 22 is reflected off the reflecting surface 50, transmitted through the transparent substrate 6, and passed into the phosphor 22, therefore the light extraction efficiency of the light emitting device 1C is high.

### Sixth Embodiment

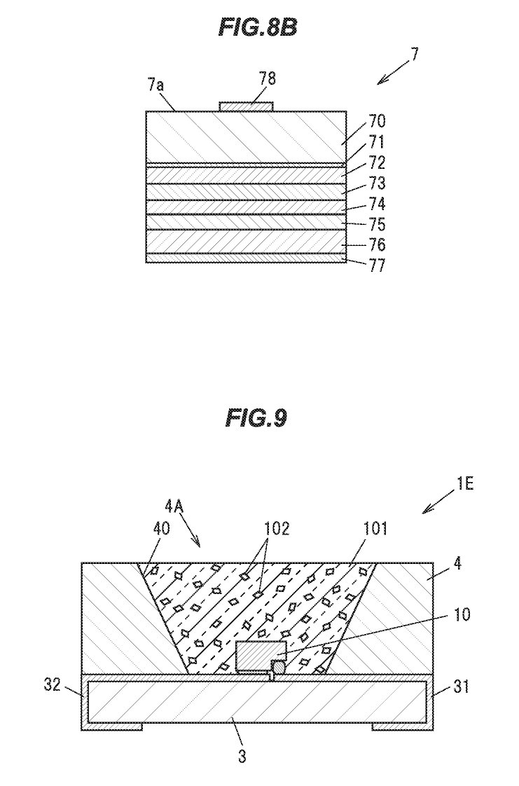

Next, a sixth embodiment of the present invention will be described with reference to FIGS. 8A and 8B. FIG. 8A is a vertical cross sectional view showing a light emitting device 1D in the sixth embodiment, and FIG. 8B is a vertical cross sectional view showing a light emitting element 7 constituting that light emitting device 1D. As shown in FIG. 8A, the present embodiment differs from the fourth embodiment in the configuration of its light emitting element and the arrangement thereof. Hereinafter, constituent elements of the light emitting device 1D having the same functions and configurations as those of the second, the third or the fourth embodiment will be given common reference characters, and descriptions thereof will be omitted.

In the light emitting device 1D, the light emitting element 7 is arranged on a wiring section 32 provided on a ceramic substrate 3. The light emitting element 7, as shown in FIG. 8B, is formed by in turn stacking a Ga₂O₃ substrate 70, a buffer layer 71, a Si-doped n⁺-GaN layer 72, a Si-doped n-AlGaN layer 73, an MQW (Multiple-Quantum Well) layer 74, a Mg-doped p-AlGaN layer 75, a Mg-doped p⁺-GaN layer 76, and a p-electrode 77. Further, on the opposite surface of the Ga₂O₃ substrate 70 to the buffer layer 71 is being provided an n-electrode 78.

The Ga₂O₃ substrate 70 is made of β-Ga₂O₃ having n-type conductivity. The MQW layer 74 is a light emitting layer having an InGaN/GaN multiple quantum well structure. The p-electrode 77 is a transparent electrode made of an ITO (Indium Tin Oxide), and is being electrically connected to the wiring section 32. The n-electrode 78 is being connected to a wiring section 31 of the ceramic substrate 3 by a bonding wire 321. Note that the element substrate may use SiC (silicon carbide), in place of the β-Ga₂O₃.

When the light emitting element 7 configured as described above is energized, electrons are injected through the n-electrode 78, the Ga₂O₃ substrate 70, the buffer layer 71, the Si-doped n⁺-GaN layer 72, and the Si-doped n-AlGaN layer 73 into the MQW layer 74, while holes are injected through the p-electrode 77, the Mg-doped p⁺-GaN layer 76, and the Mg-doped p-AlGaN layer 75 into the MQW layer 74, resulting in bluish light emission. This bluish light emitted is transmitted through the Ga₂O₃ substrate 70, etc., is emitted from an emitting surface 7a of the light emitting element 7, and is incident on a first surface 22a of the phosphor 22.

The phosphor 22 absorbs the bluish light emitted by the light emitting element 7 from the first surface 22a facing the emitting surface 7a of the light emitting element 7, and emits yellow fluorescence from a second surface 22b to the outside.

In this manner, some of the blue light passed into the phosphor 22 is absorbed into the phosphor 22, wavelength converted, and emitted from the second surface 22b of the phosphor 22 as yellow light, while the remaining of the blue light passed into the phosphor 22 is emitted from the second surface 22b of the phosphor 22 without being absorbed into the phosphor 22. Since the blue color and the yellow color are complementary to each other, the light emitting device 1D emits white light with the blue light and the yellow light mixed together therein.

### Seventh Embodiment

Next, a seventh embodiment of the present invention will be described with reference to FIG. 9. FIG. 9 is a vertical cross sectional view showing a light emitting device 1E in the seventh embodiment. As shown in FIG. 9, the present embodiment differs from the second embodiment in the configuration of its phosphor and the arrangement thereof. Hereinafter, constituent elements of the light emitting device 1E having the same functions and configurations as those of the second embodiment will be given common reference characters, and descriptions thereof will be omitted.

As shown in FIG. 9, the light emitting device 1E includes a light emitting element 10 such as an LED (light emitting diode), a ceramic substrate 3 for supporting the light emitting element 10, a body 4 made of a white resin, and a transparent member 101 for sealing the light emitting element 10.

A particulate phosphor 102 is being dispersed in the transparent member 101. The phosphor 102 is made of the single crystal phosphor in the first embodiment, and is obtained for example by pulverizing the single crystal phosphor ingot 92 produced in the first embodiment.

The transparent member 101 is, for example, a transparent resin such as a silicone based resin, an epoxy based resin or the like, or a transparent inorganic material such as a glass or the like.

The phosphor 102 dispersed in the transparent member 101 absorbs some of bluish light emitted from the light emitting element 10, and emits yellowish light having an emission peak at a wavelength of 514 to 546 nm, for example. The bluish light not absorbed into the phosphor 102, and the yellowish fluorescence emitted from the phosphor 102 are mixed together, and white light is emitted from the light emitting device 1E.

The transparent member 101 and the phosphor 102 in the present embodiment may be applied to another embodiment. In other words, the transparent member 101 and the phosphor 102 in the present embodiment may be used in place of the transparent resin 8 and the phosphor 21, respectively, in the third embodiment.

### Eighth Embodiment

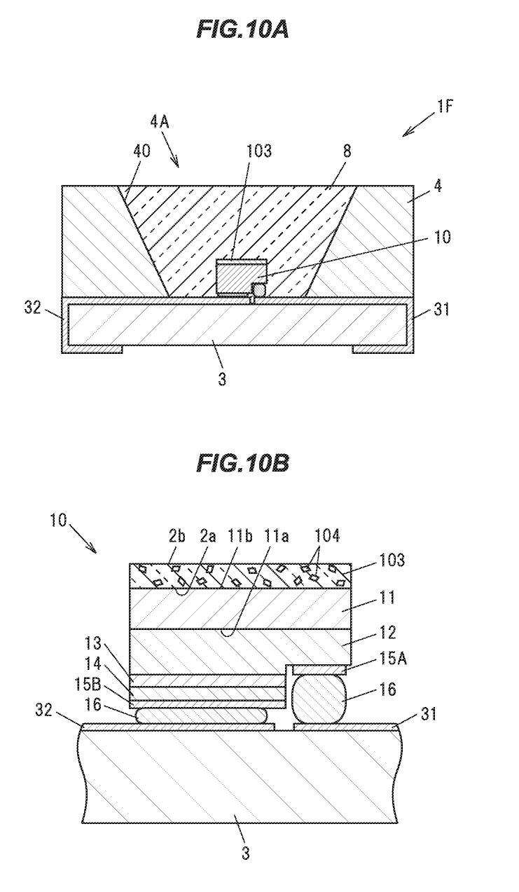

Next, an eighth embodiment of the present invention will be described with reference to FIGS. 10A and 10B. FIG. 10A is a vertical cross sectional view showing a light emitting device 1F in the eighth embodiment, and FIG. 10B is a vertical cross sectional view showing a light emitting element 10 constituting that light emitting device 1F and its peripheral portion. As shown in FIGS. 10A and 10B, the present embodiment differs from the second embodiment in the condition of its phosphor and the arrangement thereof. Hereinafter, constituent elements of the light emitting device 1F having the same functions and configurations as those of the second embodiment will be given common reference characters, and descriptions thereof will be omitted.

As shown in FIG. 10A, the light emitting device 1F includes a light emitting element 10, such as an LED (light emitting diode), a transparent member 103, which is provided in such a manner as to cover the light emitting surface of the light emitting element 10, a ceramic substrate 3 for supporting the light emitting element 10, a body 4 made of a white resin, and a transparent resin 8 for sealing the light emitting element 10 and the transparent member 103.

A particulate phosphor 104 is being dispersed in the transparent member 103. The phosphor 104 is made of the single crystal phosphor in the first embodiment, and is obtained for example by pulverizing the single crystal phosphor ingot 92 produced in the first embodiment.

The transparent member 103 is, for example, a transparent resin such as a silicone based resin, an epoxy based resin or the like, or a transparent inorganic material such as a glass or the like. The transparent member 103 has the same shape and size as the phosphor 2 of the second embodiment, for example.

The phosphor 104 dispersed in the transparent member 103 absorbs some of bluish light emitted from the light emitting element 10, and emits yellowish light having an emission peak at a wavelength of 514 to 546 nm, for example. The bluish light not absorbed into the phosphor 104, and the yellowish fluorescence emitted from the phosphor 104 are mixed together, and white light is emitted from the light emitting device 1F.

The transparent member 103 and the phosphor 104 in the present embodiment may be applied to other embodiments. For example, the transparent member 103 and the phosphor 104 in the present embodiment may be used in place of the phosphor 21 in the third embodiment, or the phosphor 22 in the fourth, the fifth, or the sixth embodiment.

### Ninth Embodiment

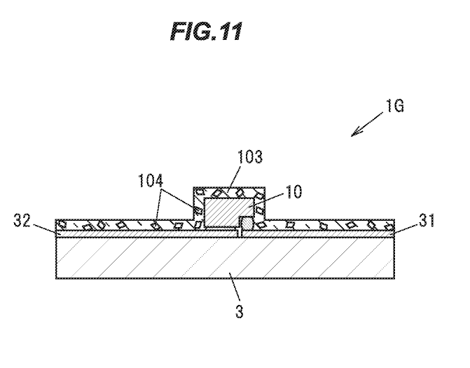

Next, a ninth embodiment of the present invention will be described with reference to FIG. 11. FIG. 11 is a vertical cross sectional view showing a light emitting device 1G in the ninth embodiment. As shown in FIG. 11, the present embodiment differs from the eighth embodiment in the shape of its transparent member including a particulate single crystal phosphor. Hereinafter, constituent elements of the light emitting device 1G having the same functions and configurations as those of the eighth embodiment will be given common reference characters, and descriptions thereof will be omitted.

As shown in FIG. 11, the light emitting device 1G includes a light emitting element 10, such as an LED (light emitting diode), a ceramic substrate 3 for supporting the light emitting element 10, and a transparent member 103, which is provided in such a manner as to cover a surface of the light emitting element 10 and an upper surface of the ceramic substrate 3.

A particulate phosphor 104 is being dispersed in the transparent member 103. The phosphor 104 is made of the single crystal phosphor in the first embodiment, and is obtained for example by pulverizing the single crystal phosphor ingot 92 produced in the first embodiment.

The transparent member 103 is, for example, a transparent resin such as a silicone based resin, an epoxy based resin or the like, or a transparent inorganic material such as a glass or the like. Incidentally, although for the reason of its producing process using a coating method, etc., the transparent member 103 of the present embodiment is formed over the ceramic substrate 3 as well as over the surface of the light emitting element 10 in some cases, the transparent member 103 may not be formed over the ceramic substrate 3.

The phosphor 104 dispersed in the transparent member 103 absorbs some of bluish light emitted from the light emitting element 10, and emits yellowish light having an emission peak at a wavelength of 514 to 546 nm, for example. The bluish light not absorbed into the phosphor 104, and the yellowish fluorescence emitted from the phosphor 104 are mixed together, and white light is emitted from the light emitting device 1G.

### Advantageous Effects of the Embodiments

With the above described embodiments, it is possible to produce the phosphor superior in the quantum efficiencies and the temperature quenching property. Further, the use of the phosphor superior in the quantum efficiencies and the temperature quenching property allows for achieving the light emitting device having superior features such as high intensity, high power, long life, etc.

As apparent from the above descriptions, the present invention is not limited to the above described exemplary embodiments and illustrated examples, but various design alterations may be made within the scope specified in each of the appended claims. For example, although one example of the method for producing the phosphor has been shown, the phosphor of the present invention is not limited to that produced in this one example. Further, the light emitting element and the phosphor may be sealed with a so-called bullet shaped resin. Alternatively, one light emitting device may be configured in such a manner as to have a multiplicity of light emitting elements. Furthermore, the light emitting device may be constructed by combining a multiplicity of single monocrystalline phosphors, such as a single crystal phosphor, which uses light of a light emitting element emitting bluish light as exciting light to emit yellowish light, and a single crystal phosphor, which emits light of a color tone different from that of the aforementioned single crystal phosphor.

Further, the light emitting devices in the above embodiments such as LED light emitting devices or the like, or the single crystal phosphors to be used in those light emitting devices are high in energy efficiency, and capable of ensuring energy saving, therefore have an energy-saving effect.

### INDUSTRIAL APPLICABILITY

The single crystal phosphors, which exhibit superior properties even under high temperature conditions, and the light emitting devices using those phosphors are provided.

### REFERENCE SINGS LIST

1, 1A, 1B, 1C, 1D, 1E, 1F, 1G LIGHT EMITTING DEVICE
2, 21, 22, 102, 104 PHOSPHOR
3 CERAMIC SUBSTRATE
2a, 21a, 22a FIRST SURFACE
2b, 21b, 22b SECOND SURFACE
4,5 BODY
51 HOLDING PORTION
4A, 5A OPENING
4b UPPER SURFACE
6 TRANSPARENT SUBSTRATE
10, 10A, 7 LIGHT EMITTING ELEMENT
11 ELEMENT SUBSTRATE
11a FIRST PRINCIPAL PLANE
11b SECOND PRINCIPAL PLANE
12 n-TYPE GaN LAYER
13 LIGHT EMITTING LAYER
14 p-TYPE GaN LAYER
15A n-SIDE ELECTRODE
15B p-SIDE ELECTRODE
16 BUMP
31, 32, 61, 62 WIRING SECTION
311, 321, 611, 621 BONDING WIRE
40, 50 REFLECTING SURFACE
140 TRANSPARENT ELECTRODE
140b SURFACE
70 Ga₂O₃SUBSTRATE
71 BUFFER LAYER
72 n⁺-GaN LAYER
73 n-AlGaN LAYER
74 MQW LAYER
75 p-AlGaN LAYER
76 p⁺-GaN LAYER
77 p-ELECTRODE
78 n-ELECTRODE
80 CRYSTAL GROWING APPARATUS
81 CRUCIBLE
82 CYLINDRICAL CONTAINER
83 HIGH FREQUENCY COIL
90 MELT
91 SEED CRYSTAL
92 SINGLE CRYSTAL PHOSPHOR INGOT
101, 103 TRANSPARENT MEMBER

1. A single crystal phosphor, comprising a composition represented by a composition formula (Y_{1-x-y-z}LuₓGd_{y}Ce_{z})₃₊ₐAl₅₋ₐO₁₂(0≦x≦0.9994, 0≦y≦0.0669, 0.0002≦z≦0.0067, −0.016≦a≦0.315).

2. The single crystal phosphor according to claim 1, wherein a fluorescence peak wavelength at a temperature of 25 degrees C. and an exciting light peak wavelength of 450 nm is not shorter than 514 nm and not longer than 544 nm, and
wherein an internal quantum efficiency at a temperature of 300 degrees C. and an exciting light peak wavelength of 450 nm is not lower than 0.90.

3. The single crystal phosphor according to claim 1, wherein a fluorescence peak wavelength at a temperature of 25 degrees C. and an exciting light peak wavelength of 450 nm is longer than 544 nm and not longer than 546 nm, and
wherein an internal quantum efficiency at a temperature of 300 degrees C. and an exciting light peak wavelength of 450 nm is not lower than 0.80.

4. The single crystal phosphor according to claim 1, wherein a fluorescence peak wavelength at a temperature of 25 degrees C. and an exciting light peak wavelength of 450 nm is not shorter than 514 nm and not longer than 544 nm, and
wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.90.

5. The single crystal phosphor according to claim 1, wherein a fluorescence peak wavelength at a temperature of 25 degrees C. and an exciting light peak wavelength of 450 nm is longer than 544 nm and not longer than 546 nm, and
wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.80.

6. The single crystal phosphor according to claim 1, wherein a fluorescence peak wavelength at a temperature of 25 degrees C. and an exciting light peak wavelength of 450 nm is not shorter than 514 nm and not longer than 544 nm, and
wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.85.

7. The single crystal phosphor according to claim 1, wherein a fluorescence peak wavelength at a temperature of 25 degrees C. and an exciting light peak wavelength of 450 nm is longer than 544 nm and not longer than 546 nm, and
wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.80.

8. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 1.

9. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 4.

10. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 5.

11. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 6.

12. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 7.

13. The single crystal phosphor according to claim 2, wherein a fluorescence peak wavelength at a temperature of 25 degrees C. and an exciting light peak wavelength of 450 nm is not shorter than 514 nm and not longer than 544 nm, and
wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.90.

14. The single crystal phosphor according to claim 3, wherein a fluorescence peak wavelength at a temperature of 25 degrees C. and an exciting light peak wavelength of 450 nm is longer than 544 nm and not longer than 546 nm, and
wherein a value of a ratio of an internal quantum efficiency at a temperature of 300 degrees C. and an exciting light peak wavelength of 450 nm, to an internal quantum efficiency at a temperature of 25 degrees C. and an exciting light peak wavelength of 450 nm is not lower than 0.80.

15. The single crystal phosphor according to claim 2, wherein a fluorescence peak wavelength at a temperature of 25 degrees C. and an exciting light peak wavelength of 450 nm is not shorter than 514 nm and not longer than 544 nm, and
wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.85.

16. The single crystal phosphor according to claim 3, wherein a fluorescence peak wavelength at a temperature of 25 degrees C. and an exciting light peak wavelength of 450 nm is longer than 544 nm and not longer than 546 nm, and
wherein a value of a ratio of an external quantum efficiency at a temperature of 300 degrees C. and an exciting light peak wavelength of 450 nm, to an external quantum efficiency at a temperature of 25 degrees C. and an exciting light peak wavelength of 450 nm is not lower than 0.80.

17. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 2.

18. A light emitting device, comprising:
a light emitting element to emit bluish light; and
a single crystal phosphor to absorb the light emitted by the light emitting element and emit yellowish fluorescence,
wherein the single crystalline phosphor comprises the single crystal phosphor according to claim 3.
